(19) United States
(12) Patent Application Publication
(10) Pub. No.: US 2007/0148926 A1
(43) Pub. Date: Jun. 28, 2007

(54) Dual halo implant for improving short channel effect in three-dimensional tri-gate transistors

(75) Inventors: Suman Datta, Beaverton, OR (US); Jack T. Kavalieros, Portland, OR (US); Justin K. Brask, Portland, OR (US); Brian S. Doyle, Portland, OR (US); Amlan Majumdar, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/321,128

(22) Filed: Dec. 28, 2005

(51) Int. Cl. H01L 21/04

(52) U.S. Cl. 438/510

(57) ABSTRACT

A method for providing halo implants in a tri-gate structure is described. Implantation is performed at two different angels to assure a halo for the top transistor and a halo for the side transistors.

### FIELD OF THE INVENTION

The invention relates to halo implants in field-effect transistors.

### PRIOR ART AND RELATED ART

It is well known to implant doping under the gates of field-effect transistors, generally after the formation of a shallow, extension source and drain region and before the formation of the side spacers. The implantation is used to form doping halos, in some applications to adjust the threshold voltage, and to combat short channel effects, This implantation may provide compensation for variations in the critical dimension of the gate, See, for instance, U.S. Pat. No. 6,020,244and U.S. Publication 2004/0061187.

Sometimes dual implants are used to provide dual thresholds for both NMOS and PMOS transistor. Examples of this are shown in U.S. Publications 2003/0203579 and 2003/0122198.

### BRIEF DESCRIPTION OF THE DRAWINGS

FIG. 1 is a cross-sectional, elevation view of a semiconductor body and a gate during ion implantation as performed in the prior art.

FIG. 2A is a cross-sectional, elevation view of a semiconductor body and gate during a first ion implantation at a first angle and first direction as used in one embodiment of the present invention.

FIG. 2B illustrates the structure of FIG. 2A during a second ion implantation performed at an opposite direction to the implantation shown in FIG. 2A.

FIG. 2C illustrates the structure of FIG. 2B during another ion implantation in the same direction as that of FIG. 2A, however, at a second angle.

FIG. 2D illustrates the structure of FIG. 2C during yet another ion implantation at a direction opposite to that of FIG. 2C and at the second angle.

FIG. 3 is a perspective view illustrating the four ion implantations shown in FIGS. 2A-2D.

FIG. 4 is a graph illustrating the dopant concentration versus depth for a single halo implant angle and for a dual halo implant at two different angles.

### DETAILED DESCRIPTION

A method for providing a halo implant particularly suited for a tri-gate transistor is described. In the following description, specific details such as concentration levels are discussed to provide a thorough understanding of the present invention. It will be apparent to one skilled in the art, that the present invention may be practiced without these specific details. In other instances, well-known processes needed to carry out ion implantation are not described in detail in order to not unnecessarily obscure the present invention.

Tri-gate transistors may be looked at as constituting a top transistor, similar to a conventional planar transistor, and two side wall transistors. Usually, a single angled halo implant is used from opposite directions to, for instance, adjust the threshold voltage of the transistors and to control the short channel effects. If this implantation is targeted deep (nearly vertical) in order to control the side transistors and lower plane of the tri-gate transistor, which is most susceptible to short channel effect, the threshold voltage of the top transistor is too low. On the other hand, if the halo implant is at a shallow angle and relatively low energy, the bottom of the transistor is lightly doped, making the transistor susceptible to subsurface punchthrough (e.g. source to drain tunneling). Moreover, the source/drain extension regions are counter doped, leading to a high external resistance.

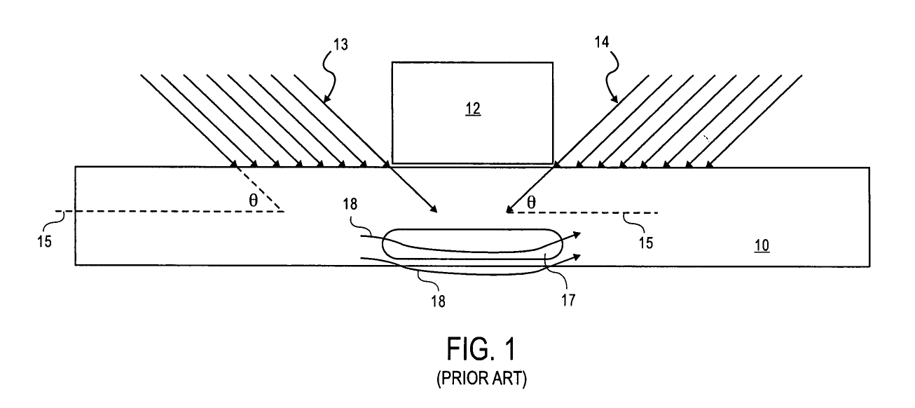

FIG. 1 illustrates a semiconductor body or fin 10 having an axis 15. The body 10 may be formed on a silicon-oxide-insulator (SOI) substrate or may be formed from a bulk substrate such as a monocrystalline silicon substrate. While the process described below may be used for both bodies, it is perhaps more important where the bodies are formed on a bulk substrate. The bodies on a bulk substrate may be formed by selective epitaxial growth or by selectively etching a substrate so as to define the body 10. A tri-gate 12 insulated from the body is generally formed about at least three sides of the body. The tri-gate may be formed in a replacement gate process, for instance, using a high k dielectric and a metal gate with a targeted work function.

In a typical halo implant, a dopant species opposite to that of the source and drain region is used to mitigate short channel effects. In FIG. 1 such dopant is shown being implanted at a relatively shallow angle θ relative to the axis 15 of the body 10, in a first direction (beam 13) and from the opposite direction (beam 14). At the angle θ, there is a deep subsurface punchthrough problem that remains, as indicated by the region 17. Moreover, region 17 can cause unwanted current paths, as indicated by the current paths 18 of FIG. 1. Ideally, there should be a plane of implanted atoms towards the bottom of the body to block leakage in the plane of the substrate. (This typically is not a problem in an SOI substrate.) As mentioned earlier, if the angle θ, is made larger so that the beam is more near vertical, insufficient implantation occurs under the gate, resulting in too low a threshold voltage and a high off state current in the top transistor.

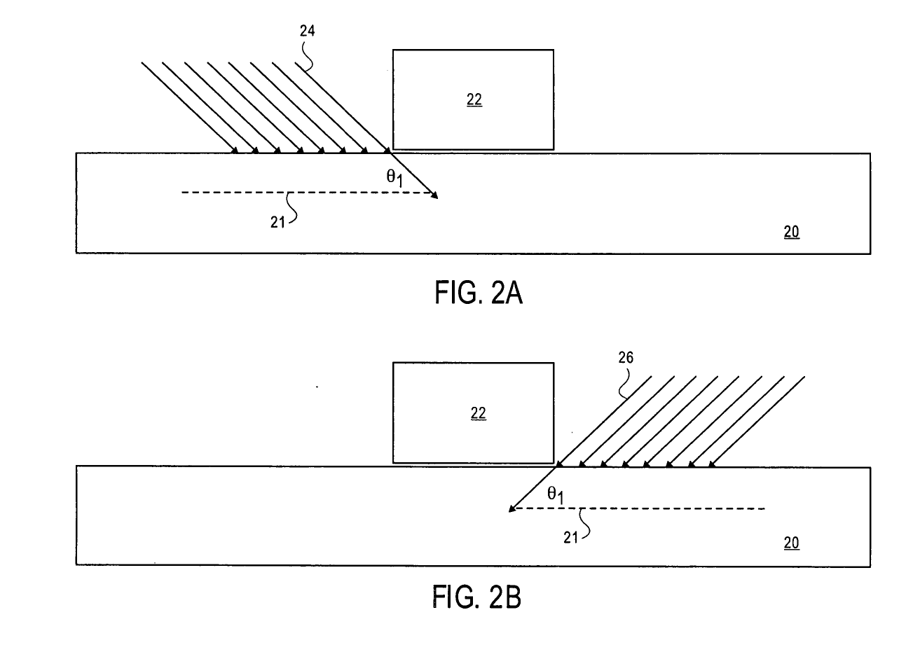

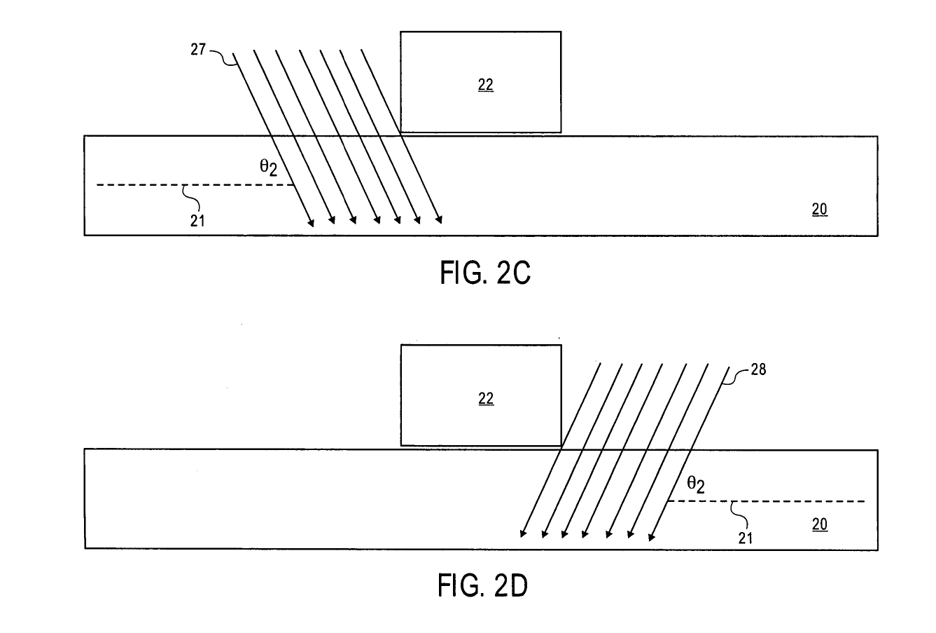

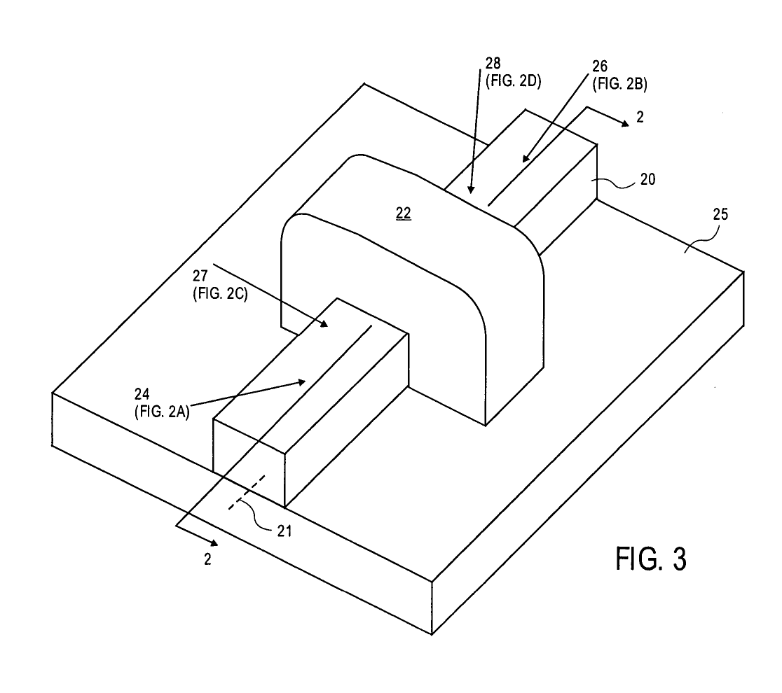

As will be seen in FIGS. 2A-2D, implantation occurs at two different angles,θ, from opposite directions. The resulting halo doping in the lower portions of the body, controls short channel effects for the side transistors. The implantation at the shallow angle provides a sufficient halo for the top transistor, again to control threshold voltage and short channel effects.

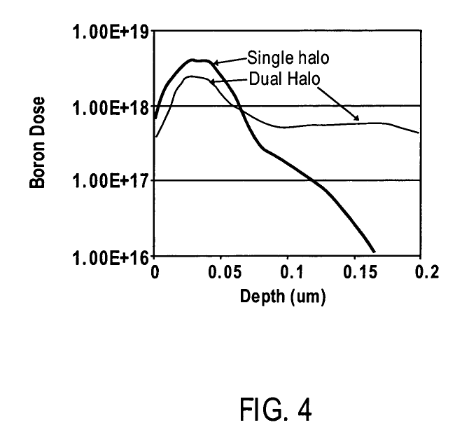

Referring now to FIG. 2A, a semiconductor body 20, such as a monocrystalline silicon body formed on a bulk silicon substrate, is illustrated. A tri-gate structure is shown in cross-sectional, elevation view; this view is taken through section line 2-2 of FIG. 3. (The substrate 25 of FIG. 3 on which the body 20 is defined, is not shown in FIGS. 2A-2D.) In FIG. 2A, first ion implantation is depicted by beam 24 occurring in a first direction at an angle θ₁ with respect to the axis 21 of the body 20. This angle is a relatively shallow angle which causes the ions to be implanted relatively high in the body 20 beneath the tri-gate 22. For an enhancement mode, an n channel transistor, a p type dopant boron is implanted in FIG. 2A, as well as in FIGS. 2B-2D. For an n channel transistor, the four implementations of FIGS. 4A-4B implant a p type dopant. By way of example, for a body 20 having a height of 20 nm and a width of 20 nm, the angle θ₁ may be approximately 40-55 degrees with boron implanted at an energy level of 0.5-3 keV.

In FIG. 2B, the implantation is shown occurring again at the angle θ₁, as represented by beam 26, however, from an opposite direction, so as to implant under the gate 22 from its opposite side when compared to FIG. 2A. This typically is done by rotating the wafer in its plane through 180°. The same implantation conditions as used for FIG. 2A may be used in FIG. 2B.

In FIG. 2C, a third implantation is illustrated at a steeper angle θ₂ relative to the axis 21 of the body 20. (While in the Figures the beam is shown at different angles relative to the fixed axis 21, in practice, the different angles θ are most often obtained by tilting the wafer with respect to a fixed beam.) This assures that the ions are implanted deep beneath the gate 22 in the body 20. As mentioned earlier, this provides a plane of doping to reduce the leakage through the bulk substrate. By way of example, in FIG. 2C, again for an n channel enhancement mode transistor, boron can be implanted where θ₂ is equal to 55-70 degrees, at an energy level of 0.5-3 keV.

In FIG. 2D, implantation again occurs, as represented by beam 28, at the angle θ₂ relative to the axis 21 of the body 20, however, from an opposite direction to that of FIG. 2C. Again, this can be done by rotating the wafer in its plane through 180° to allow the implantation to occur from the opposite direction from that shown in FIG. 2D. The same implantation conditions used in FIG. 2C may be used for FIG. 2D.

Note that the implantations of FIGS. 2C and 2D avoid having insufficient implantation in the region 17 shown in FIG. 1.

FIG. 3 again shows the body 20 on a substrate 25 along with the tri-gate 22. The four implantations described in conjunction with FIGS. 2A and 2D are all shown in FIG. 3 to provide a better view of the direction and angles of the implantations. The implantation of FIG. 2A, with the beam 24 at angle θ₁, is shown relative to the axis 21 of the body 20. Additionally, the shallow angle θ₁ of FIG. 2B is shown with the beam 26 in FIG. 3. The steeper angle of θ₂ of FIGS. 2C and 2D and the beams 27 and 28, respectively, are also shown in FIG. 3. Note the order in which the implantations of FIGS. 2A-2D is performed is not critical. Any order will work.

In some instances, bodies such as body 20 may also be disposed perpendicular to the body 20 on the substrate 25. When that is the case, four additional implantations are used, each of which is in a direction 90° from the direction shown in FIG. 3. This may be achieved by simply rotating the wafer in its plane by ±90° to implant the bodies traverse to body 20.

FIG. 4 illustrates the concentration of boron doping from both a single halo implant and a dual halo implant. As can be seen for the single halo implant such as shown in FIG. 1, there is a substantial drop off in doping in the body with depth. This drop off is from a peak of approximately 0.5×10¹⁹ cm⁻³ near the top of the body to 2 magnitudes less doping by 0.15 μm of depth in the body. In contrast, with the dual droping of FIGS. 2A-2D, the dioubg remains relatively constant at about 1×10¹⁸ cm⁻³ through 0.2 μm of depth in the body. This provides the punchthrough protection and reduces leakage for both the top and side transistors associated with the tri-gate transistor.

Thus, a halo implantation method using two different angles of implantation for a three-dimensional transistor has been described.

What is claimed is:

1. A method for implanting a body in a field-effect transistor comprising:
directing a first ion beam at a first angle relative to an axis of the body to implant ions in the body under a gate;
directing a second ion beam at a second angle relative to the axis of the body, the second angle being different than the first angle to implant ions in the body under the gate.

2. The method of claim 1, wherein both the first and second ion beams implant ions of the same species under the gate which gate is disposed around three sides of the body.

3. The method of claim 1, wherein the body is formed from a bulk semiconductor substrate.

4. The method of claim 3, wherein the substrate comprises silicon.

5. The method defined by claim 1, wherein the first and second ion beams are both directed from opposite directions of the axis so as to implant ions under the gate from opposite sides of the gate at the first and second angles.

6. The method defined by claim 5, wherein the first and second ion beams comprise a p-type ion.

7. The method defined by claim 5, wherein the first and second ion beams comprise an n-type ion.

8. The method defined by claim 5, wherein the body is a raised body on a bulk semiconductor substrate.

9. A method for implanting a halo under a tri-gate of a semiconductor device comprising:
implanting ions under the gate at two different angles from one side of the gate; and
implanting ions under the gate at the two different angles from an opposite side of the gate.

10. The method of claim 9, wherein the ions are an n type dopant.

11. The method of claim 9, wherein the ions are a p type dopant.

12. The method of claim 9, wherein the ions are implanted into a silicon body.

13. The method of claim 10, wherein the silicon body is formed from a bulk silicon substrate.

14. The method of claim 12, wherein the ions are implanted to form a plane at the bottom of the body, so as to reduce leakage current in the substrate.

15. A method for implanting the top transistor and side transistor in a tri-gate transistor comprising:
directing a first beam at a first angle to form a first halo on the sides and bottom of a body; and
directing a second beam at a second angle, different from the first angle, to form a second halo in an upper portion of the body.

16. The method of claim 15, wherein the first and second beams are directed for first and second directions so as to form the first and second halos on opposite sides of the tri-gate.

17. The method of claim 16, wherein the first and second beams implant a p type dopant.

18. The method of claim 16, wherein the first and second beams implant an n type dopant.

19. The method of claim 17, wherein the first and second beams are at different energy levels.

20. The method of claim 18, wherein the first and second beams are at different energy levels.
